(19) United States
(12) Patent Application Publication
(10) Pub. No.: US 2024/0321733 A1
(43) Pub. Date: Sep. 26, 2024

(54) INTERCONNECTION STRUCTURE AND METHODS OF FORMING THE SAME

(71) Applicant: TAIWAN SEMICONDUCTOR MANUFACTURING COMPANY, LTD., Hsinchu (TW)

(72) Inventors: Chia-Pang KUO, Taoyuan (TW); Jo-Lin LAN, Kaohsiung (TW); Chun Hsiang YANG, New Taipei (TW); Ming-Yuan GAO, Hsinchu (TW); Chi-Feng LIN, Hsinchu (TW)

(21) Appl. No.: 18/209,655

(22) Filed: Jun. 14, 2023

Related U.S. Application Data
(60) Provisional application No. 63/454,430, filed on Mar. 24, 2023.

(51) Int. Cl. H01L 23/528; H01L 21/768

(52) U.S. Cl. CPC H01L 23/528; H01L 21/76802; H01L 21/76834; H01L 21/76843; H01L 21/76879

(57) ABSTRACT

An interconnection structure and methods of forming the same are described. The interconnection structure includes a dielectric layer, a dielectric material disposed over the dielectric layer, and first and second conductive features disposed in the dielectric material. The first and second conductive features each has rounded top corners, the first conductive feature has a first width and a first height, and the second conductive feature has a second width substantially less than the first width and a second height substantially the same as the first height. The structure further includes an etch stop layer disposed on the first and second conductive features and third and fourth conductive features disposed in the dielectric material and the etch stop layer. The third conductive feature is in contact with the first conductive feature, and the fourth conductive feature is in contact with the second conductive feature.

### CROSS-REFERENCE TO RELATED APPLICATIONS

This application claims priority to U.S. Provisional Application Ser. No. 63/454,430 filed Mar. 24, 2023, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (e.g., the number of interconnected devices per chip area) has generally increased while geometry size (e.g., the smallest component (or line) that can be created using a fabrication process) has decreased. This scaling down process generally provides benefits by increasing production efficiency and lowering associated costs. However, scaling down has also led to challenges that may not have been presented by previous generations at larger geometries.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are cross-sectional views of one of the various stages of manufacturing a semiconductor device structure, in accordance with some embodiments.

FIG. 2 is a cross-sectional side view of a stage of manufacturing an interconnection structure, in accordance with some embodiments.

FIGS. 3A-3J are cross-sectional side views of various stages of manufacturing an interconnection structure, in accordance with some embodiments.

FIGS. 4A-4C are cross-sectional side views of one of various stages of manufacturing the interconnection structure, in accordance with some embodiments.

FIG. 5 is a cross-sectional side view of one of various stages of manufacturing the interconnection structure, in accordance with some embodiments.

FIGS. 6A and 6B are cross-sectional side views of one of various stages of manufacturing the interconnection structure, in accordance with some embodiments.

FIG. 7 is a cross-sectional side view of a conductive feature disposed in the interconnection structure, in accordance with some embodiments.

FIGS. 8A-8F are cross-sectional side views of the conductive feature of FIG. 7, in accordance with some embodiments.

FIG. 9 is a cross-sectional side view of a plurality of conductive features disposed in the interconnection structure, in accordance with some embodiments.

FIG. 10 is a chart showing a relationship between the height and the width of the conductive feature formed by different electrochemical deposition processes, in accordance with some embodiments.

FIG. 11 is a cross-sectional side view of one of various stages of manufacturing the interconnection structure, in accordance with some embodiments.

FIG. 12 is a cross-sectional side view of a three-dimensional structure, in accordance with some embodiments.

FIG. 13 is a cross-sectional side view of one of various stages of manufacturing the interconnection structure, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

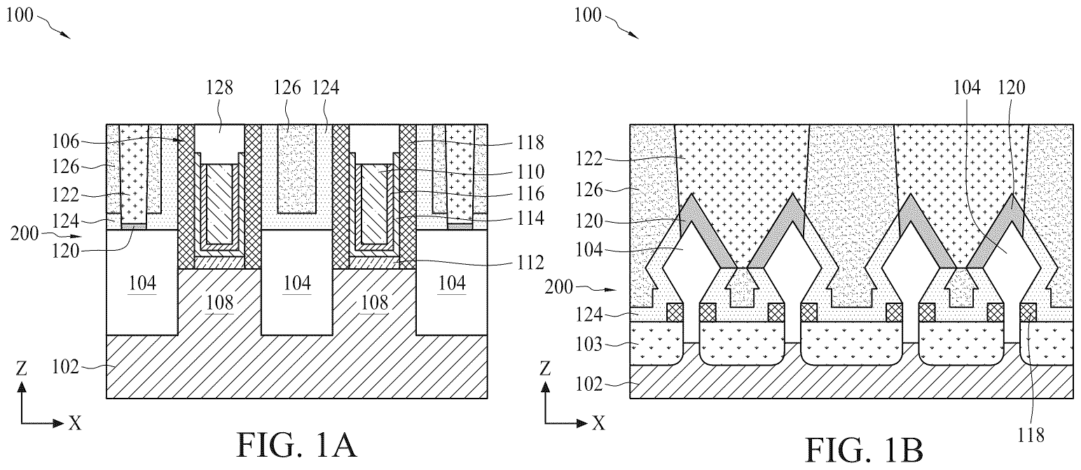

FIGS. 1A and 1B are cross-sectional side views of one of various stages of manufacturing the semiconductor device structure 100, in accordance with some embodiments. As shown in FIGS. 1A and 1B, the semiconductor device structure 100 includes a substrate 102 and one or more devices 200 formed on the substrate 102. The substrate 102 may be a semiconductor substrate. In some embodiments, the substrate 102 includes a single crystalline semiconductor layer on at least the surface of the substrate 102. The substrate 102 may include a single crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), and indium phosphide (InP). For example, the substrate 102 is made of Si. In some embodiments, the substrate 102 is a silicon-on-insulator (SOI) substrate, which includes an insulating layer (not shown) disposed between two silicon layers. In one aspect, the insulating layer is an oxygen-containing material, such as an oxide.

The substrate 102 may include one or more buffer layers (not shown) on the surface of the substrate 102. The buffer layers can serve to gradually change the lattice constant from that of the substrate to that of the source/drain regions. The buffer layers may be formed from epitaxially grown single crystalline semiconductor materials such as, but not limited to Si, Ge, germanium tin (GeSn), SiGe, GaAs, InSb, GaP, GaSb, InAlAs, InGaAs, GaSbP, GaAsSb, GaN, GaP, and InP. In one embodiment, the substrate 102 includes SiGe buffer layers epitaxially grown on the silicon substrate 102. The germanium concentration of the SiGe buffer layers may increase from 30 atomic percent germanium for the bottom-most buffer layer to 70 atomic percent germanium for the top-most buffer layer.

The substrate 102 may include various regions that have been suitably doped with impurities (e.g., p-type or n-type impurities). The dopants are, for example phosphorus for an n-type fin field effect transistor (FinFET) and boron for a p-type FinFET.

As described above, the devices 200 may be any suitable devices, such as transistors, diodes, imaging sensors, resistors, capacitors, inductors, memory cells, or a combination thereof. In some embodiments, the devices 200 are transistors, such as planar field effect transistors (FETs), FinFETs, nanostructure transistors, or other suitable transistors. The nanostructure transistors may include nanosheet transistors, nanowire transistors, gate-all-around (GAA) transistors, multi-bridge channel (MBC) transistors, or any transistors having the gate electrode surrounding the channels. An example of the device 200 formed on the substrate 102 is a FinFET, which is shown in FIGS. 1A and 1B. The device 200 includes source/drain (S/D) regions 104 and gate stacks 106. Each gate stack 106 may be disposed between S/D regions 104 serving as source regions and S/D regions 104 serving as drain regions. For example, each gate stack 106 may extend along the Y-axis between a plurality of S/D regions 104 serving as source regions and a plurality of S/D regions 104 serving as drain regions. As shown in FIG. 1A, two gate stacks 106 are formed on the substrate 102. In some embodiments, more than two gate stacks 106 are formed on the substrate 102. Channel regions 108 are formed between S/D regions 104 serving as source regions and S/D regions 104 serving as drain regions.

The S/D regions 104 may include a semiconductor material, such as Si or Ge, a III-V compound semiconductor, a II-VI compound semiconductor, or other suitable semiconductor material. Exemplary S/D region 104 may include, but are not limited to, Ge, SiGe, GaAs, AlGaAs, GaAsP, SiP, InAs, AlAs, InP, GaN, InGaAs, InAlAs, GaSb, AIP, GaP, and the like. The S/D regions 104 may include p-type dopants, such as boron; n-type dopants, such as phosphorus or arsenic; and/or other suitable dopants including combinations thereof. The S/D regions 104 may be formed by an epitaxial growth method using CVD, atomic layer deposition (ALD) or molecular beam epitaxy (MBE). The channel regions 108 may include one or more semiconductor materials, such as Si, Ge, GeSn, SiGe, GaAs, InSb, GaP, GaSb, InAlAs, InGaAs, GaSbP, GaAsSb, GaN, GaP, or InP. In some embodiments, the channel regions 108 include the same semiconductor material as the substrate 102. In some embodiments, the devices 200 are FinFETs, and the channel regions 108 are a plurality of fins disposed below the gate stacks 106. In some embodiments, the devices 200 are nanostructure transistors, and the channel regions 108 are surrounded by the gate stacks 106.

Each gate stack 106 includes a gate electrode layer 110 disposed over the channel region 108 (or surrounding the channel region 108 for nanostructure transistors). The gate electrode layer 110 may be a metal-containing material such as tungsten, cobalt, aluminum, ruthenium, copper, multilayers thereof, or the like, and can be deposited by ALD, plasma enhanced chemical vapor deposition (PECVD), MBD, physical vapor deposition (PVD), or any suitable deposition technique. Each gate stack 106 may include an interfacial dielectric layer 112, a gate dielectric layer 114 disposed on the interfacial dielectric layer 112, and one or more conformal layers 116 disposed on the gate dielectric layer 114. The gate electrode layer 110 may be disposed on the one or more conformal layers 116. The interfacial dielectric layer 112 may include a dielectric material, such as an oxygen-containing material or a nitrogen-containing material, or multilayers thereof, and may be formed by any suitable deposition method, such as CVD, PECVD, or ALD. The gate dielectric layer 114 may include a dielectric material such as an oxygen-containing material or a nitrogen-containing material, a high-k dielectric material having a k value greater than that of silicon dioxide, or multilayers thereof. The gate dielectric layer 114 may be formed by any suitable method, such as CVD, PECVD, or ALD. The one or more conformal layers 116 may include one or more barrier layers and/or capping layers, such as a nitrogen-containing material, for example tantalum nitride (TaN), titanium nitride (TiN), or the like. The one or more conformal layers 116 may further include one or more work-function layers, such as aluminum titanium carbide, aluminum titanium oxide, aluminum titanium nitride, or the like. The term “conformal” may be used herein for case of description upon a layer having substantial same thickness over various regions. The one or more conformal layers 116 may be deposited by ALD, PECVD, MBD, or any suitable deposition technique.

Gate spacers 118 are formed along sidewalls of the gate stacks 106 (e.g., sidewalls of the gate dielectric layers 114). The gate spacers 118 may include silicon oxycarbide, silicon nitride, silicon oxynitride, silicon carbon nitride, the like, multi-layers thereof, or a combination thereof, and may be deposited by CVD, ALD, or other suitable deposition technique.

Portions of the gate stacks 106 and the gate spacers 118 may be formed on isolation regions 103. The isolation regions 103 are formed on the substrate 102. The isolation regions 103 may include an insulating material such as an oxygen-containing material, a nitrogen-containing material, or a combination thereof. The insulating material may be formed by a high-density plasma chemical vapor deposition (HDP-CVD), a flowable chemical vapor deposition (FCVD), or other suitable deposition process. In one aspect, the isolation regions 103 includes silicon oxide that is formed by a FCVD process.

A contact etch stop layer (CESL) 124 is formed on a portion of the S/D regions 104 and the isolation region 103, and an interlayer dielectric (ILD) layer 126 is formed on the CESL 124. The CESL 124 can provide a mechanism to stop an etch process when forming openings in the ILD layer 126. The CESL 124 may be conformally deposited on surfaces of the S/D regions 104 and the isolation regions 103. The CESL 124 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be deposited by CVD, PECVD, ALD, or any suitable deposition technique. The ILD layer 126 may include an oxide formed by tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), organosilicate glass (OSG), SiOC, and/or any suitable low-k dielectric materials (e.g., a material having a dielectric constant lower than silicon dioxide), and may be deposited by spin-on, CVD, FCVD, PECVD, PVD, or any suitable deposition technique.

A silicide layer 120 is formed on at least a portion of each S/D region 104, as shown in FIGS. 1A and 1B. The silicide layer 120 may include a material having one or more of WSi, CoSi, NiSi, TiSi, MoSi and TaSi. In some embodiments, the silicide layer 120 includes a metal or metal alloy silicide, and the metal includes a noble metal, a refractory metal, a rare earth metal, alloys thereof, or combinations thereof. A conductive contact 122 is disposed on each silicide layer 120. The conductive contact 122 may include a material having one or more of Ru, Mo, Co, Ni. W. Ti, Ta, Cu, Al, TiN or TaN, and the conductive contact 122 may be formed by any suitable method, such as electro-chemical plating (ECP), or PVD. The silicide layer 120 and the conductive contact 122 may be formed by first forming an opening in the ILD layer 126 and the CESL 124 to expose at least a portion of the S/D region 104, then forming the silicide layer 120 on the exposed portion of the S/D region 104, and then forming the conductive contact 122 on the silicide layer 120.

A dielectric material 128 may be formed over the gate stack 106, and a conductive contact (not shown) is formed in the dielectric material 128, as shown in FIG. 1A. The dielectric material 128 may be a nitrogen-containing material, such as SiCN. The conductive contact may include the same material as the conductive contact 122. The conductive contact may be electrically connected to the gate electrode layer 110.

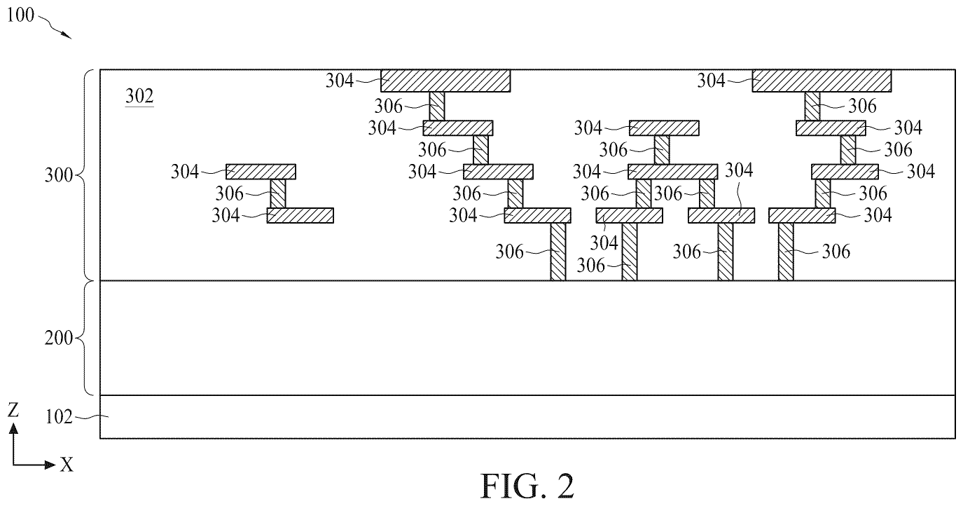

The semiconductor device structure 100 may further include an interconnection structure 300 disposed over the devices 200 and the substrate 102, as shown in FIG. 2. The interconnection structure 300 includes various conductive features, such as a first plurality of conductive features 304 and second plurality of conductive features 306, and an intermetal dielectric (IMD) layer 302 to separate and isolate various conductive features 304, 306. In some embodiments, the first plurality of conductive features 304 are conductive lines and the second plurality of conductive features 306 are conductive vias. The interconnection structure 300 includes multiple levels of the conductive features 304, and the conductive features 304 are arranged in each level to provide electrical paths to various devices 200 disposed below. The conductive features 306 provide vertical electrical routing from the devices 200 to the conductive features 304 and between conductive features 304. For example, the bottom-most conductive features 306 of the interconnection structure 300 may be electrically connected to the conductive contacts 122 (FIG. 1A). The conductive features 304 and conductive features 306 may be made from one or more electrically conductive materials, such as one or more layers of graphene, metal, metal alloy, metal nitride, or silicide. For example, the conductive features 304 and the conductive features 306 are made from copper, aluminum, aluminum copper alloy, titanium, titanium nitride, tantalum, tantalum nitride, titanium silicon nitride, zirconium, gold, silver, cobalt, nickel, tungsten, tungsten nitride, tungsten silicon nitride, platinum, chromium, molybdenum, hafnium, other suitable conductive material, or a combination thereof.

The IMD layer 302 includes one or more dielectric materials to provide isolation functions to various conductive features 304, 306. The IMD layer 302 may include multiple dielectric layers embedding multiple levels of conductive features 304, 306. The IMD layer 302 is made from a dielectric material, such as SiOₓ, SiOₓC_{y}H_{z}, or SiOₓC_{y}, where x, y and z are integers or non-integers. In some embodiments, the IMD layer 302 includes a low-k dielectric material having a k value less than that of silicon oxide. In some embodiments, the IMD layer 302 has a k value ranging from about 1.5 to about 3.9.

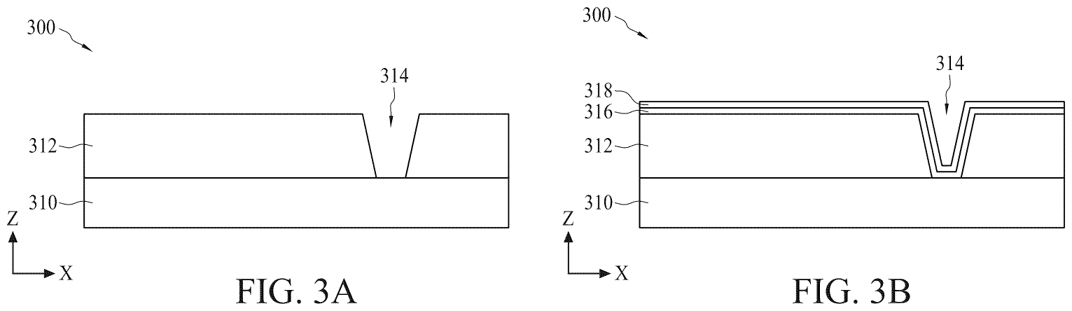

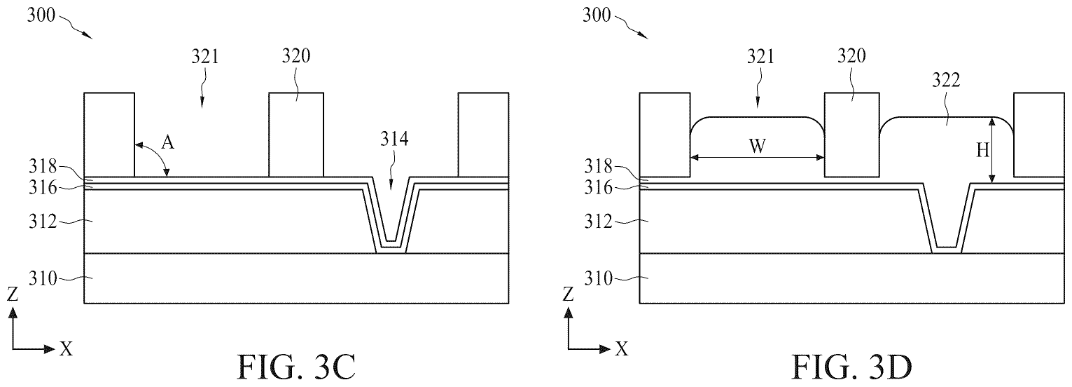

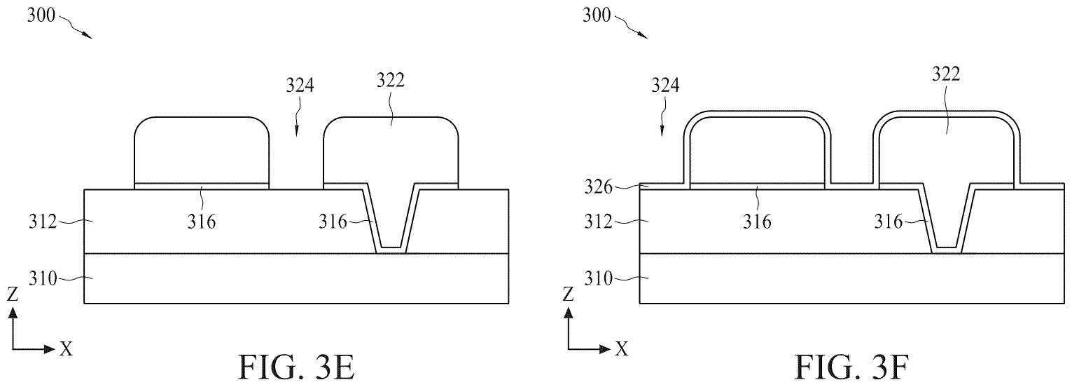

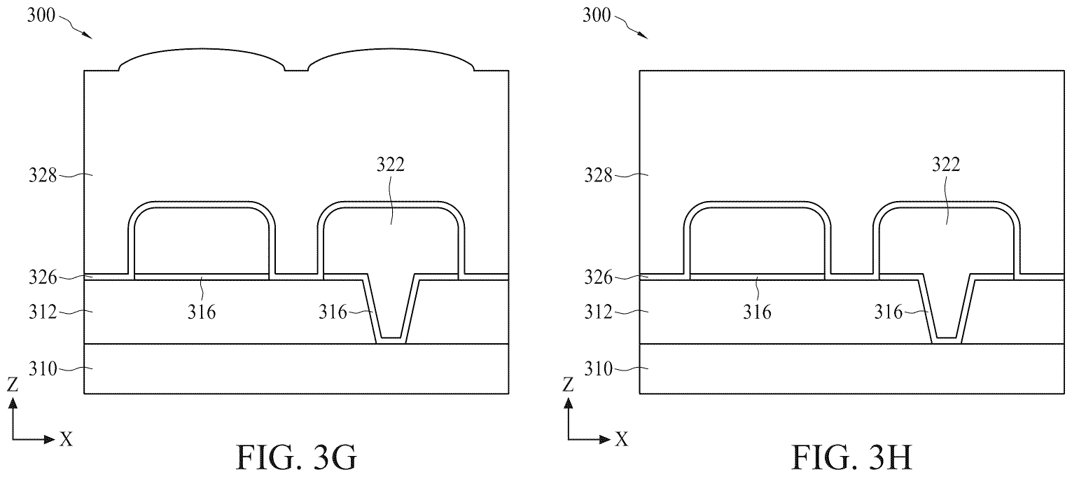

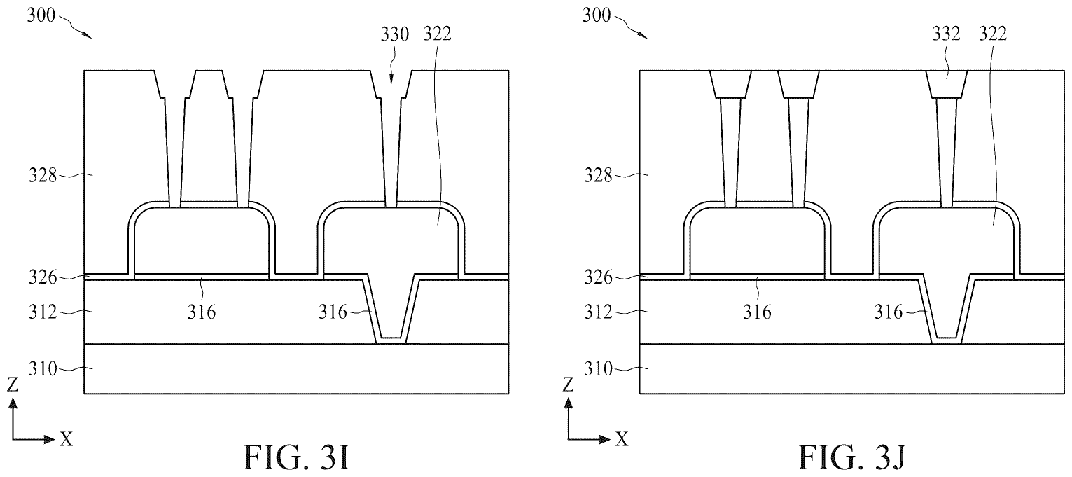

FIGS. 3A-3J show exemplary sequential processes for manufacturing the interconnection structure 300, in accordance with some embodiments. It is understood that additional operations can be provided before, during, and after processes shown by FIGS. 3A-3J, and some of the operations described below can be replaced or eliminated, for additional embodiments of the process. The order of the operations/processes may be interchangeable.

FIGS. 3A-3J are cross-sectional side views of various stages of manufacturing the interconnection structure 300, in accordance with some embodiments. As shown in FIG. 3A, a dielectric layer 312 is formed on a conductive layer 310, and an opening 314 is formed in the dielectric layer 312 to expose a portion of the conductive layer 310. The conductive layer 310 may be the conductive feature 304 shown in FIG. 2 and may include the same material as the conductive feature 304. The dielectric layer 312 may include the same material as the IMD layer 302. In some embodiments, the dielectric layer 312 may be a dielectric layer of the IMD layer 302. The opening 314 may be a via opening, as shown in FIG. 3A. In some embodiments, the opening 314 includes a trench located over a via, and the opening 314 is formed by a dual damascene process.

As shown in FIG. 3B, a barrier layer 316 is deposited on the dielectric layer 312 and in the opening 314, and a seed layer 318 is deposited on the barrier layer 316. In some embodiments, the barrier layer 316 includes an electrically conductive material, such as Ta, TaN. Ti, TiN, TiW, or other suitable material. The barrier layer 316 may be a single layer or a multilayer structure. For example, the barrier layer 316 may include a TaN layer and a Ta layer, a TaN layer and a TiN layer, a Ta layer and a Ti layer, or any suitable combination of electrically conductive material. The seed layer 318 may include an electrically conductive material, such as a copper. The seed layer 318 helps with the subsequent deposition process to form the conductive feature 322 (FIG. 3D).

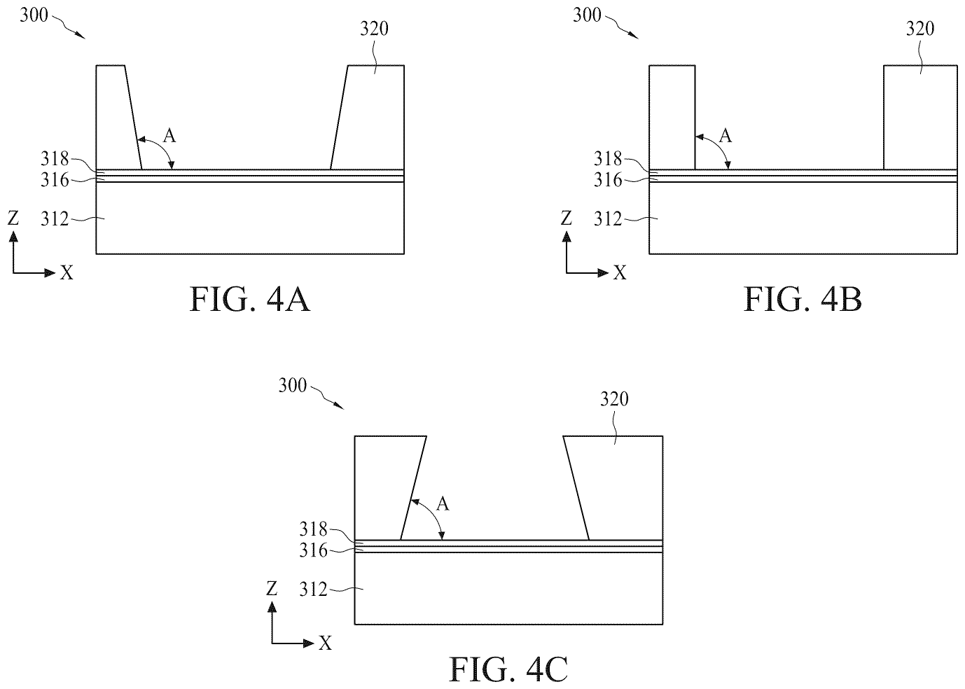

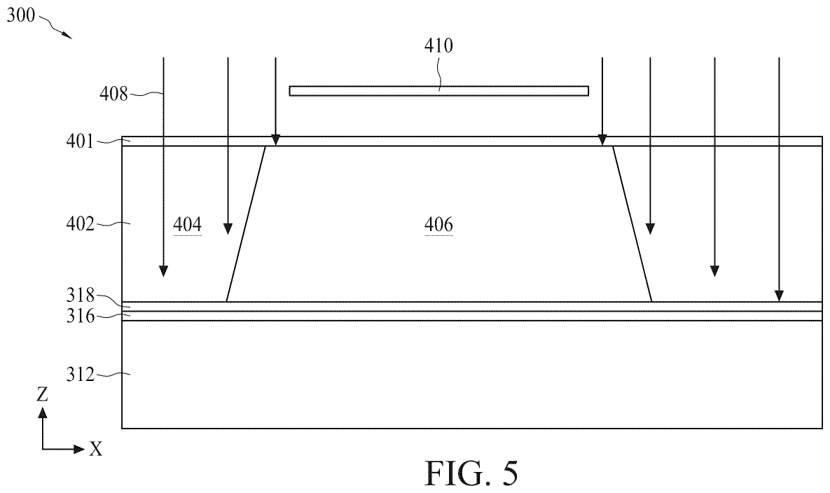

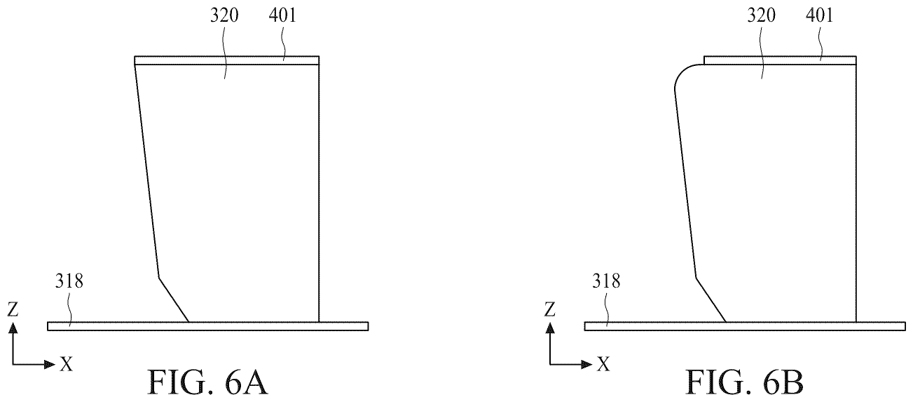

As shown in FIG. 3C, a patterned resist layer 320 is formed on the seed layer 318. The patterned resist layer 320 forms a plurality of openings 321 to expose portions of the seed layer and the opening 314. The patterned resist layer 320 may be a photoresist layer. In some embodiments, the patterned resist layer 320 is a negative resist layer. During the patterning process, the radiation exposed portion of the negative resist become substantially insoluble in the developer, while the unexposed (or less exposed) portions of the negative resist are soluble in the developer. The patterned resist layer 320 includes any suitable material, such as a polymer or a copolymer. The pattering process is described in detail in FIGS. 5 and 6A to 6C. In some embodiments, an angle A is formed between a sidewall of the patterned resist layer 320 and the seed layer 318, as shown in FIG. 3C. Referring to FIGS. 4A, 4B, and 4C, the angle A may be a right angle (FIG. 4B), an acute angle (FIG. 4C), or an obtuse angle (FIG. 4A). In some embodiments, the angle A is an acute angle, and the conductive feature 322 (FIG. 3D) formed in the openings 321 has a trapezoid shape and is more stable. As a result, the conductive features 322 would not collapse during subsequent processes. In some embodiments, the plurality of openings 321 have different critical dimensions (CDs) along the X-axis.

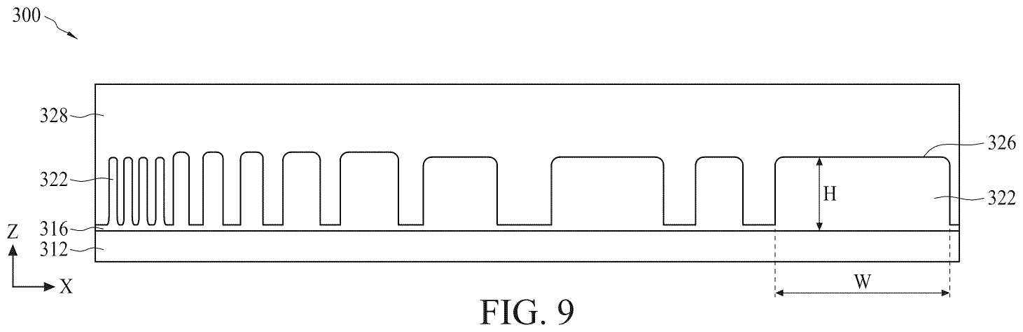

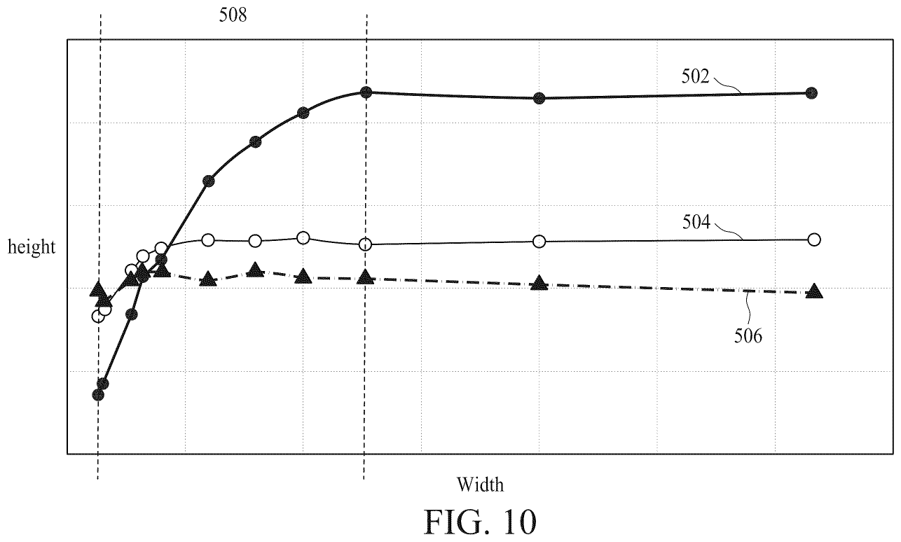

As shown in FIG. 3D, the conductive features 322 are formed in the openings 321. The conductive features 322 fill the opening 314 and partially fill the openings 321. The portion of the conductive feature 322 filling the opening 314 may be a via portion, and the portion of the conductive feature 322 partially filling the opening 321 may be a line portion. In some embodiments, at least one conductive feature 322 includes the via portion. In some embodiments, none of the conductive features 322 include the via portion. In some embodiments, all of the conductive features 322 include the via portion. The conductive feature 322 includes an electrically conductive material, such as a metal, for example copper. In some embodiments, the conductive feature 322 includes a doped metal, such as Mn doped Cu or Al doped Cu. As described above, the openings 321 have different CDs. Thus, the conductive features 322 have different widths W. The different widths W of the conductive features 322 may be a result of circuit design. In some embodiments, the heights H of the conductive features 322 are different as a result of the different CDs of the openings 321. Different heights H of the conductive features 322 may lead to delamination after subsequent processes, such as thermal cycling and hybrid bonding. Thus, in some embodiments, an electrochemical deposition (ECD) process is performed to deposit the conductive features 322 having substantially different widths W and substantially the same heights H. The conductive features 322 having different widths W and same heights H and the ECD process are described in detail in FIGS. 9 and 10.

As shown in FIG. 3E, the patterned resist layer 320 is removed, and the portions of the seed layer 318 and the barrier layer 316 located under the patterned resist layer 320 are also removed. The patterned resist layer 320 and the portions of the seed layer 318 and the barrier layer 316 may be removed by the same or different processes. In some embodiments, a wet stripping process is performed to remove the patterned resist layer 320 and the portions of the seed layer 318 and the barrier layer 316. The wet stripping process may not substantially affect the conductive features 322 because the thickness of the portions of the seed layer 318 and barrier layer 316 are much thinner than the thickness of the conductive features 322. In some embodiments, the wet stripping process may be tuned to control the shape of the conductive features 322. The removal of the patterned resist layer 320 and the portions of the seed layer 318 and the barrier layer 316 forms openings 324 between adjacent conductive features 322, and portions of the dielectric layer 312 are exposed, as shown in FIG. 3E.

As shown in FIG. 3F, an etch stop layer 326 is formed on the exposed portions of the dielectric layer 312 and the conductive features 322. The etch stop layer 326 may include any suitable material, such as SiN, AlN, or Al₂O₃. The etch stop layer 326 may be formed by any suitable process. In some embodiments, the etch stop layer 326 is a conformal layer and is formed by ALD. Next, a dielectric material 328 is formed on the etch stop layer 326, as shown in FIG. 3G. The dielectric material 328 may include any suitable dielectric material and may be formed by any suitable process. In some embodiments, the dielectric material 328 includes SiO₂ or SiN. As shown in FIG. 3H, a planarization process is performed on the dielectric material 328. In some embodiments, the planarization process is a chemical mechanical polish (CMP) process. The CMP process is performed on a single material (i.e., the dielectric material 328), which lowers the cost compared to a CMP process performed on multiple materials, such as a dielectric material and a metal.

As shown in FIG. 3I, openings 330 are formed in the dielectric material 328 and the etch stop layer 326 to expose portions of the conductive features 322. In some embodiments, the openings 330 are formed by a dual damascene process, and each opening 330 includes a bottom via opening and a top trench. As described above, the heights H of the conductive features 322 are substantially the same. If the heights H of the conductive features 322 are substantially different, over etching or under etching during the formation of the openings 330 may occur. Next, conductive features 332 are formed in the openings 330, as shown in FIG. 3J. The conductive feature 332 includes an electrically conductive material, such as a metal. In some embodiments, each conductive feature 332 includes a bottom via portion and a top line portion. After another planarization process, such as a CMP process, the top surface of the interconnection structure 300 includes metal surfaces (i.e., the top surfaces of the conductive features 332) and a dielectric surface (i.e., the top surface of the dielectric material 328). The top surface of the interconnection structure 300 may be bonded to a second interconnection structure 300 using direct bonding method, such as hybrid bonding. The second interconnection structure 300 may be part of a second semiconductor device structure 100, and the bonded structure may form three-dimensional integrated circuits (3DICs).

FIG. 5 is a cross-sectional side view of one of various stages of manufacturing the interconnection structure 300, in accordance with some embodiments. As shown in FIG. 5, an exposure process is performed on a resist layer 402 to form the patterned resist layer 320 (FIG. 3C). An optional top anti-reflective coating (TARC) 401 may be formed on the resist layer 402. A mask 410 may be used to block the light 408, such as an extreme ultraviolet (EUV) light, from reaching portions 406 of the resist layer 402, while the light 408 reaches portions 404 of the resist layer 402. As described above, in some embodiments, the resist layer 402 is a negative resist, the exposed portion 404 of the negative resist become substantially insoluble in the developer, while the unexposed (or less exposed) portions 406 of the negative resist are soluble in the developer. In some embodiments, by using a small exposure dosage, such as from about 150 mJ/cm² to about 250 mJ/cm², the sidewalls of the portions 404 can have an undercut profile. In other words, the angle A (FIG. 3C) is an acute angle. During the developing process, a developer (i.e., wet etchants), such as KOH or tetramethylammonium hydroxide (TMAH), may be used to remove the portions 406 and to form a footing profile in the sidewalls of the portions 404, as shown in FIG. 6A. In some embodiments, after the developing process, a plasma ashing process may be performed to remove the portions of the resist layer 402 in the openings 314 (FIG. 3B). The plasma ashing process further modifies the sidewalls of the portions 404, such that the footing profile is further extended outward, and the top of the sidewall is rounded, as shown in FIG. 6B.

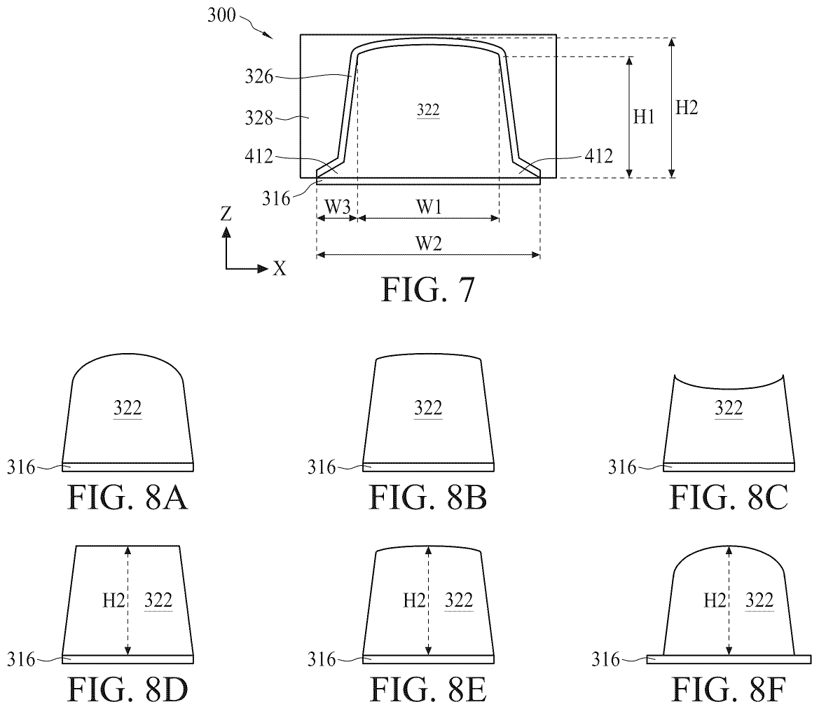

FIG. 7 is a cross-sectional side view of the conductive feature 322 disposed in the interconnection structure 300, in accordance with some embodiments. As shown in FIG. 7, the conductive feature 322 has a trapezoid shape and includes footing portions 412 as a result of the small exposure dosage during the exposure process, the developer during the developing process, and plasma ashing process. In some embodiments, the top portion of the conductive feature 322 has a width W1, and the bottom portion of the conductive feature 322 has a width W2. The width W1 may range from about 1 micron to about 50 microns, and the ratio of the width W1 to the width W2 may range from about 0.84 to about 0.94. If the ratio of the width W1 to the width W2 is less than about 0.84, the conductive features 322 having a smaller width W1, such as less than about 3 microns, may have increased contact resistance. On the other hand, if the ratio of the width W1 to the width W2 is greater than about 0.94, the stability of the conductive features 322 during subsequent processes may be reduced. In some embodiments, the width W3 of each footing portion 412 is the difference between the width W1 and the width W2 divided by two. The ratio of the width W3 of the footing portion 412 to the width W2 may range from about 0.03 to about 0.08. The top surface of the conductive feature 322 is a convex, concave, or flat surface. In some embodiments, the conductive feature 322 has a first height H1 measured at the edge of the top surface and a height H2 measured at the center of the conductive feature 322, and the ratio of the height H1 to the height H2 may range from about 0.85 to about 1.05. In some embodiments, the height H2 ranges from about 2 microns to about 6 microns. In some embodiments, the ratio of the width W1 to the height H1 is greater than 0.5, which leads to improved stability, less resist layer bridge, and improved ECD height loading control when forming the conductive features 322.

The trapezoid shape with the footing portions 412 improve the stability of the conductive feature 322 during subsequent processes, such as the wet stripping process described in FIG. 3E. Furthermore, the trapezoid shape can ensure the dielectric material 328 to be seam free. The conductive feature 322 may include a via portion (not shown) as shown in FIG. 3J. The conductive feature 322 formed by the processes described in FIGS. 3A to 3J has various benefits over the traditional processes of forming the conductive features in an interconnection structure. For example, the CMP process is performed on a single material, thus reducing the cost. There are less hillock on the conductive features 322 having the height H2 greater than about 2 microns due to the adhesion to the etch stop layer 326, which increases yield.

FIGS. 8A-8F are cross-sectional side views of the conductive feature 322 of FIG. 7, in accordance with some embodiments. As shown in FIGS. 8A to 8C, the top surface of the conductive feature 322 may be substantially convex, substantially flat, or substantially concave, respectively. In other words, the ratio of the height H1 to the height H2 may be substantially less than 1 (as shown in FIG. 8A), about 1 (as shown in FIG. 8B), or substantially greater than 1 (as shown in FIG. 8C). The profile of the top surface may be controlled by tuning the ECD process. As shown in FIGS. 8D to 8F, top corners of the top portion of the conductive feature 322 may be sharp (as shown in FIG. 8D), less sharp (as shown in FIG. 8E), or rounded (as shown in FIG. 8F). The height H2 of the conductive feature 322 shown in FIG. 8D is the greatest, the height H2 of the conductive feature 322 shown in FIG. 8E is less than the height H2 of the conductive feature 322 shown in FIG. 8D, and the height H2 of the conductive feature 322 shown in FIG. 8F is less than the height H2 of the conductive feature 322 shown in FIG. 8E. The sharpness of the top corners of the top portion and the height H2 of the conductive feature 322 may be controlled by the wet stripping process to remove the patterned resist layer 320 (FIG. 3D). The longer the wet stripping process, the more rounded top corners and smaller height H2. In some embodiments, the duration of the wet stripping process ranges from about 30 seconds to about 90 seconds. The etch rate of the conductive feature 322 during the wet stripping process may range from about 30 Angstroms per second to about 50 Angstroms per second.

FIG. 9 is a cross-sectional side view of a plurality of conductive features 322 disposed in the interconnection structure, in accordance with some embodiments. As described above, the widths W, which may be between the width W1 and the width W2, such as an average of the widths W1 and W2, of the conductive features 322 are substantially different, as shown in FIG. 9. For example, the narrow conductive features 322 may have a width W ranging from about 1 micron to about 5 microns. The wide conductive features 322 may have a width W ranging from about 15 microns to about 50 microns. The conductive features 322 having different widths W is formed by an ECD process that is controlled by surface reaction limit instead of mass transfer limit. As a result, the height H, which may be between the height H1 and the height H2, such as an average of the heights H1 and H2, of the conductive features 322 are substantially the same, as shown in FIG. 9. In some embodiments, the height H of a narrow conductive feature 322 is less than 10 percent smaller than the height H of a wide conductive feature 322. In other words, the ratio of the height H of a narrow conductive feature 322 to the height H of a wide conductive feature ranges from about 0.9 to about 0.99, such as from about 0.9 to about 1.

The mechanism of the ECD process is based on Ohm's Law, Fick's Law, and Butler-Volmer Equation. The total overpotential (ηₜₒₜₐₗ) equals the sum of activation overpotential (ηₐ), concentration overpotential (η_{c}), and ohmic overpotential (η_{Ω}). The activation overpotential, the concentration overpotential, and the ohmic overpotential can be determined by the following equations:

$${η}_{a} = \frac{RT}{α F} ln \frac{i}{{i}_{0}}$$

$${η}_{C} = \frac{RT}{RF} ln ( 1 - \frac{\vert i \vert}{{i}_{L}} )$$

$${η}_{Ω} = i \frac{L}{K}$$

Based on these equations, if the ECD process utilizes low current and high acid electrolyte, the concentration overpotential and the ohmic overpotential become negligible, and the total overpotential equals the activation overpotential, which is about surface reaction. As a result, the ECD process is surface reaction limited. In some embodiments, the current density of the ECD process is less than 2 ampere/square decimeter (A/dm²), such as from about 0.1 A/dm² to about 1 A/dm². Low current density helps with limiting surface reaction. The bath temperature of the ECD process is greater than about 30 degrees Celsius, such as from about 30 degrees Celsius to about 40 degrees Celsius. Higher temperature can lead to higher acidity bath. In some embodiments, the chemical concentrations can help to achieve a high acid bath. For example, the molar concentration of CuSO₄ is less than about 0.5 M, such as from about 0.1 M to about 0.3 M. Low molar concentration of CuSO₄ is for low deposition rate control. The molar concentration of H₂SO₄ is greater than 1 M, such as from about 1 M to about 3 M. Higher molar concentration of H₂SO₄ is for higher acidity bath. In some embodiments, the molar concentration of a leveler, such as derivatives of Pyridinium or Imidazolium, is less than about 0.1 M, such as about 0.025 M to about 0.075 M. Lower molar concentration of the leveler is also for low deposition rate control.

FIG. 10 is a chart showing a relationship between the height and the width of the conductive feature 322 formed by different electrochemical deposition processes, in accordance with some embodiments. As shown in FIG. 10, the data points of line 502 are from conductive features formed by conventional ECD process, the data points of line 504 are from conductive features 322 formed by an ECD process utilizing low current density, and the data points of line 506 are from conductive features 322 formed by an ECD process utilizing both low current density and high acidity bath. As shown in FIG. 10, in region 508, for the conductive features formed by the conventional ECD process, as the width increases, the height also increases. However, in region 508, for the conductive features 322 formed by ECD processes utilizing low current density or low current density along with high acidity bath, the height remains substantially constant as the width increases. In some embodiments, the change in the height is less than about 10 percent as the width increases in the region 508 for the conductive features formed by the ECD process utilizing low current density or low current density along with high acidity bath.

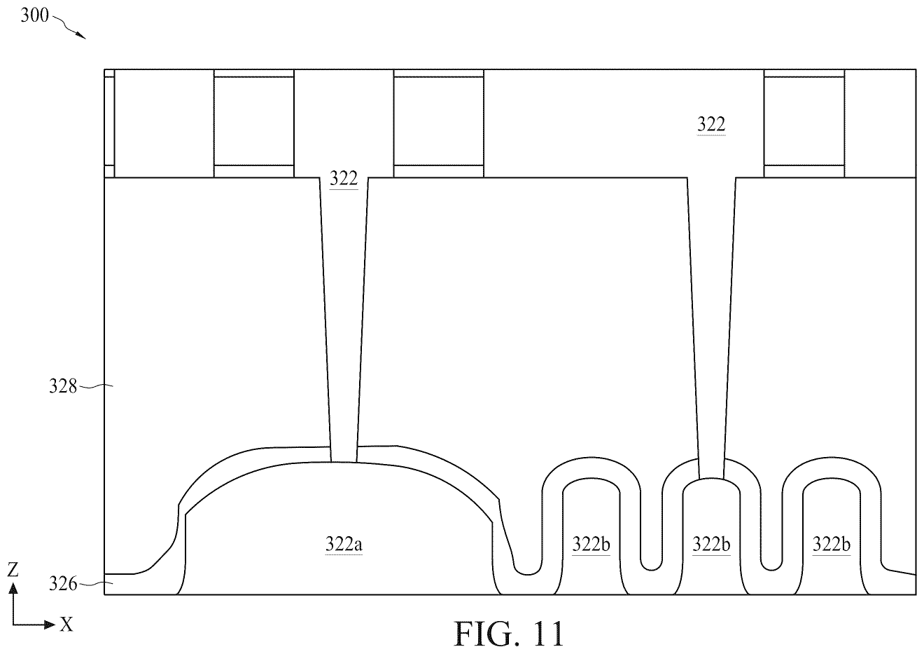

FIG. 11 is a cross-sectional side view of one of various stages of manufacturing the interconnection structure 300, in accordance with some embodiments. As shown in FIG. 11, the conductive features 322a, 322b have different widths but substantially the same heights. In some embodiments, the conductive feature 322a has a width greater than about 10 microns, such as from about 15 microns to about 50 microns, and the conductive feature 322b has a width less than about 10 microns, such as from about 1 micron to about 5 microns. The conductive feature 322a may be the wide conductive feature, and the conductive feature 322b may be the narrow conductive feature described in FIG. 9. The conductive features 322a, 332b have substantially the same height. In some embodiments, the ratio of the height of the conductive feature 322b to the height of the conductive feature 322a is greater than about 0.9, such as from about 0.9 to about 0.99. As shown in FIG. 11, each conductive feature 322a, 322b has round top corners, as a result of the wet stripping process to remove the patterned resist layer 320 (FIG. 3D).

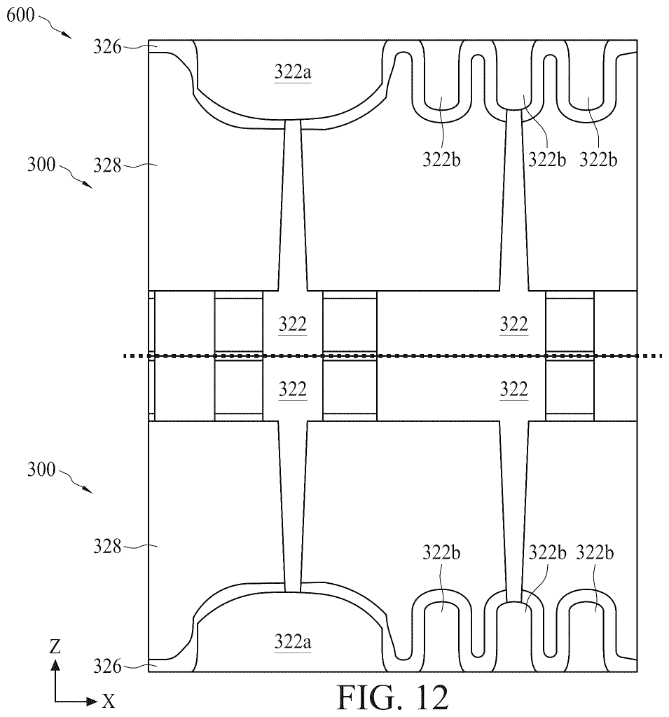

FIG. 12 is a cross-sectional side view of a three-dimensional structure 600, in accordance with some embodiments. As shown in FIG. 12, the three-dimensional structure 600 includes the interconnection structure 300 bonded to another interconnection structure 300. In some embodiments, the bonding of the interconnection structures 300 is by hybrid bonding. Each interconnection structure 300 may be part of a semiconductor device structure 100, and the three-dimensional structure 600 includes 3DICs. The three-dimensional structure 600 may be diced to form a plurality of dies, and the dies may be part of a semiconductor package, such as a surface mount integrated circuit (SoIC) package. The SoIC package may go through thermal cycling for reliability testing. The thermal cycling includes expose the SoIC package to cycles of extreme temperatures, such as from about −65 degrees Celsius to about 125 degrees Celsius. If the heights of the conductive features 322a, 322b are different, delamination of the interconnection structures 300 can occur during the thermal cycling. By forming the conductive features 322a, 322b having substantially the same heights, delamination can be avoided.

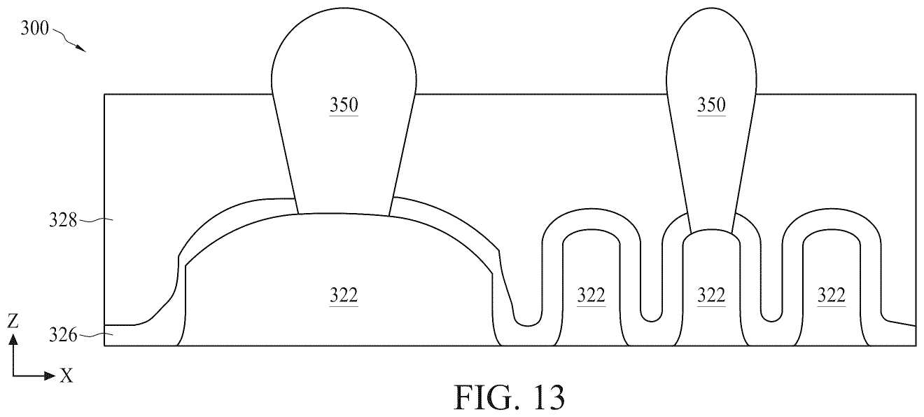

FIG. 13 is a cross-sectional side view of one of various stages of manufacturing the interconnection structure, in accordance with alternative embodiments. As shown in FIG. 13, a conductive feature 350 is formed in the dielectric material 328 and in contact with the conductive feature 322. The conductive feature 350 may be a bump extending from the dielectric material 328 to electrically connect the semiconductor device structure 100 to other parts of a package. The conductive features 322 having substantially the same heights helps to reduce or avoid over etching or under etching during the formation of openings for the conductive features 350 to be formed therein.

Embodiments of the present disclosure provide an interconnection structure 300. In some embodiments, the interconnection structure 300 includes a plurality of conductive features having different widths and substantially the same height. Some embodiments may achieve advantages. For example, the conductive features having substantially the same heights can lead to reduced delamination and reduced over etching or under etching during the formation of openings.

An embodiment is an interconnection structure. The structure includes a dielectric layer, a dielectric material disposed over the dielectric layer, and first and second conductive features disposed in the dielectric material. The first and second conductive features each has rounded top corners, the first conductive feature has a first width and a first height, and the second conductive feature has a second width substantially less than the first width and a second height substantially the same as the first height. The structure further includes an etch stop layer disposed on the first and second conductive features and between the dielectric layer and the dielectric material and third and fourth conductive features disposed in the dielectric material and the etch stop layer. The third conductive feature is in contact with the first conductive feature, and the fourth conductive feature is in contact with the second conductive feature.

Another embodiment is an interconnection structure. The structure includes a dielectric layer, a dielectric material disposed over the dielectric layer, and a first conductive feature disposed on the dielectric layer and in the dielectric material. The first conductive feature has a trapezoid shape having footing portions, a top width, and a bottom width, and a ratio of the top width to the bottom width ranges from about 0.84 to about 0.94. The structure further includes a second conductive feature disposed on the dielectric layer and in the dielectric material. The second conductive feature has a third width substantially less than an average of the top and bottom widths.

A further embodiment is a method. The method includes forming a patterned resist layer over a dielectric layer, and the patterned resist layer includes a plurality of openings having different critical dimensions. The method further includes forming a plurality of conductive features in the plurality of openings, each conductive feature of the plurality of conductive features partially fills a corresponding opening of the plurality of openings, and the plurality of conductive features have different widths and substantially the same height. The method further includes removing the patterned resist layer, depositing an etch stop layer on the dielectric layer and around the plurality of conductive features, and depositing a dielectric material on the etch stop layer and over the plurality of conductive features.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An interconnection structure, comprising:
a dielectric layer;
a dielectric material disposed over the dielectric layer;
first and second conductive features disposed in the dielectric material, wherein the first and second conductive features each has rounded top corners, the first conductive feature has a first width and a first height, and the second conductive feature has a second width substantially less than the first width and a second height substantially the same as the first height;
an etch stop layer disposed on the first and second conductive features and between the dielectric layer and the dielectric material; and
third and fourth conductive features disposed in the dielectric material and the etch stop layer, wherein the third conductive feature is in contact with the first conductive feature, and the fourth conductive feature is in contact with the second conductive feature.

2. The interconnection structure of claim 1, wherein a portion of the first conductive feature extends through the dielectric layer.

3. The interconnection structure of claim 1, wherein the first and second conductive features each has a trapezoid shape.

4. The interconnection structure of claim 3, wherein the first conductive feature comprises footing portions.

5. The interconnection structure of claim 4, wherein the first width ranges from about 15 microns to about 50 microns, and the second width ranges from about 1 micron to about 5 microns.

6. The interconnection structure of claim 1, further comprising a barrier layer disposed between the first and second conductive features and the dielectric layer.

7. An interconnection structure, comprising:
a dielectric layer;
a dielectric material disposed over the dielectric layer;
a first conductive feature disposed on the dielectric layer and in the dielectric material, wherein the first conductive feature has a trapezoid shape having footing portions, a top width, and a bottom width, and a ratio of the top width to the bottom width ranges from about 0.84 to about 0.94; and
a second conductive feature disposed on the dielectric layer and in the dielectric material, wherein the second conductive feature has a third width substantially less than an average of the top and bottom widths.

8. The interconnection structure of claim 7, wherein the first conductive feature has a first height measured at an edge of a top surface and a second height measured at a center of the top surface, and a ratio of the first height to the second height ranges from about 0.85 to about 1.05.

9. The interconnection structure of claim 7, wherein the first conductive feature has a third height, the second conductive feature has a fourth height substantially the same as the third height.

10. The interconnection structure of claim 7, wherein the first conductive feature has a third height, the second conductive feature has a fourth height, and a ratio of the fourth height to the third height ranges from about 0.9 to about 1.

11. The interconnection structure of claim 7, further comprising a third conductive feature disposed in the dielectric layer over the first conductive feature.

12. The interconnection structure of claim 11, wherein the third conductive feature has a top surface substantially coplanar with a top surface of the dielectric material.

13. The interconnection structure of claim 11, wherein the third conductive feature extends from the dielectric material.

14. A method, comprising:
forming a patterned resist layer over a dielectric layer, wherein the patterned resist layer includes a plurality of openings having different critical dimensions;
forming a plurality of conductive features in the plurality of openings, wherein each conductive feature of the plurality of conductive features partially fills a corresponding opening of the plurality of openings, and the plurality of conductive features have different widths and substantially the same height;
removing the patterned resist layer;
depositing an etch stop layer on the dielectric layer and around the plurality of conductive features; and
depositing a dielectric material on the etch stop layer and over the plurality of conductive features.

15. The method of claim 14, wherein the plurality of conductive features are formed by an electrochemical deposition process.

16. The method of claim 15, wherein a current density of the electrochemical deposition process ranges from about 0.1 ampere/square decimeter to about 1 ampere/square decimeter.

17. The method of claim 15, wherein a molar concentration of CuSO₄ used in the electrochemical deposition process ranges from about 0.1 M to about 0.3 M.

18. The method of claim 17, wherein a molar concentration of H₂SO₄ used in the electrochemical deposition process ranges from about 1 M to about 3 M.

19. The method of claim 18, wherein a molar concentration of a leveler used in the electrochemical deposition process ranges from about 0.025 M to about 0.075 M.

20. The method of claim 19, wherein a bath temperature of the electrochemical deposition process ranges from about 30 degrees Celsius to about 40 degrees Celsius.
